(19) United States
(12) Patent Application Publication
(10) Pub. No.: US 2025/0368508 A1
(43) Pub. Date: Dec. 4, 2025

(54) THERMOELECTRIC MATERIAL AND FORMING METHOD THEREFOR

(71) Applicant: SEOUL NATIONAL UNIVERSITY R&DB FOUNDATION, Seoul (KR)

(72) Inventors: In CHUNG, Seoul (KR); Hyungseok LEE, Seoul (KR)

(21) Appl. No.: 18/874,326

(22) PCT Filed: Jun. 12, 2023
(86) PCT No.: PCT/KR2023/008029

§ 371 Date: Dec. 12, 2024

(30) Foreign Application Priority Data
Jun. 16, 2022 (KR) 10-2022-0073167

(51) Int. Cl. C01B 19/00; H10N 10/01; H10N 10/852

(52) U.S. Cl. CPC C01B 19/002; C01B 19/007; H10N 10/01; H10N 10/852; C01P 2002/54; C01P 2006/32; C01P 2006/40

(57) ABSTRACT

A thermoelectric material and a forming method therefor are provided. The thermoelectric material has the following Chemical Formula 1. [Chemical Formula 1] [(Bi₂)ₘ (Bi₂Ch₃)ₙ] _{(1-y)/1}[A₂Oₓ]_{y} (In the Chemical Formula 1, Ch═Te or Se, A=Li, Na, K, Rb, or Cs, Q=S, Se, or Te, x=1 to 6, and 0≤y≤0.4). The method for forming a thermoelectric material comprises sealing and heating reactants comprising Bi, Te, Se, and A₂Qₓ (A=Li, Na, K, Rb, or Cs; Q=S, Se, or Te; x=1 to 6) to melt and react the reactants, cooling the reaction product to form an ingot, and pulverizing the ingot into powder and sintering the powder.

### TECHNICAL FIELD

The present invention relates to a thermoelectric material and a forming method therefor.

### BACKGROUND ART

Thermoelectric phenomena include the transfer of heat via the flow of electrons and holes within thermoelectric materials, as well as the movement of electrons and holes induced by heat transfer. These phenomena have diverse industrial applications, such as cooling technologies based on the Peltier effect, which generates a temperature difference at both ends of a material when an electric current is applied, and power generation technologies utilizing the Seebeck effect, which generated internal electromotive force when a temperature gradient exists within the material.

The power generation and cooling performance of the thermoelectric material are determined by the thermoelectric conversion efficiency of the p-type and n-type semiconductor materials constituting the device. The thermoelectric conversion efficiency is expressed by the dimensionless thermoelectric figure of merit (ZT=σS²T/K), which depends on the relationship among electrical conductivity (σ), thermal conductivity (K), Seebeck coefficient(S), and absolute temperature (T). However, improving the thermoelectric figure of merit is challenging due to the strong interdependence among these parameters.

### DISCLOSURE

### Technical Problem

The present invention provides a thermoelectric material having good performance.

The present invention provides a method for forming the thermoelectric material.

The other objects of the present invention will be clearly understood by reference to the following detailed description and the accompanying drawings.

### Technical Solution

A thermoelectric material according to the embodiments of the present invention has the following Chemical Formula 1.

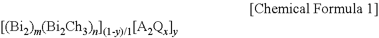

(In the Chemical Formula 1, Ch═Te or Se, A=Li, Na, K, Rb, or Cs, Q=S, Se, or Te, x=1 to 6, and 0≤y≤0.4).

The thermoelectric material may have polycrystalline properties. The thermoelectric material may be an n-type semiconductor.

The thermoelectric material may be formed by performing a solid-state synthesis reaction on reactants comprising Bi, Te, Se, and A₂Qₓ (A=Li, Na, K, Rb, or Cs; Q=S, Se, or Te; x=1 to 6).

The A may be located in at least one of the interlayer site, interstitial site, and ionic site of the Bi—Te based compound in the thermoelectric material.

A method for forming a thermoelectric material according to the embodiments of the present invention comprises sealing and heating reactants comprising Bi, Te, Se, and A₂Qₓ (A=Li, Na, K, Rb, or Cs; Q=S, Se, or Te; x=1 to 6) to melt and react the reactants, cooling the reaction product to form an ingot, and pulverizing the ingot into powder and sintering the powder.

The thermoelectric material may have the following Chemical Formula 1.

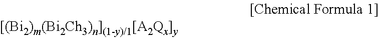

(In the Chemical Formula 1, Ch═Te or Se, A=Li, Na, K, Rb, or Cs, Q=S, Se, or Te, x=1 to 6, and 0≤y≤0.4).

The thermoelectric material may have polycrystalline properties. The thermoelectric material may be an n-type semiconductor.

The reactants may be heated at a temperature of 600 to 700° C. for 22 to 26 hours. The sintering may be performed using a spark plasma sintering method.

### Advantageous Effects

The thermoelectric material according to the embodiments invention may have good performance. The of the present thermoelectric material may possess superior electrical properties and an improved thermoelectric figure of merit. When combined with a p-type material, the thermoelectric material may enable the development of a thermoelectric module with enhanced power generation efficiency.

### DESCRIPTION OF DRAWINGS

FIG. 1 shows the power factor (PF) and thermal conductivity of Bi₂Te₃-9% K₂Se₆, a thermoelectric material according to one embodiment of the present invention compared with those of Bi₂Te₃.

FIG. 2 shows the power factor (PF) and thermoelectric figure of merit (ZT) of Bi₂Te₃-9% K₂Se₆, a thermoelectric material according to one embodiment of the present invention compared with those of Bi₂Te₃.

FIG. 3 shows the thermoelectric figure of merit (ZT) of thermoelectric materials according to other embodiments of the present invention.

### BEST MODE

Hereinafter, a detailed description will be given of the present invention with reference to the following embodiments. The purposes, features, and advantages of the present invention will be easily understood through the following embodiments. The present invention is not limited to such embodiments, but may be modified in other forms. The embodiments to be described below are nothing but the ones provided to bring the disclosure of the present invention to perfection and assist those skilled in the art to completely understand the present invention. Therefore, the following embodiments are not to be construed as limiting the present invention.

The terminology used herein is for the purpose of describing particular embodiments only and is not intended to limit the invention. It is to be understood that the singular forms “a,” “an,” and “the” include plural references unless the context clearly dictates otherwise. It will be further understood that the terms “comprises” or “has,” when used in this specification, specify the presence of stated features, integers, steps, operations, elements, and/or components, but do not preclude the presence or addition of one or more other features, integers, steps, operations, elements, components, and/or groups thereof.

A thermoelectric material according to the embodiments of the present invention has the following Chemical Formula 1.

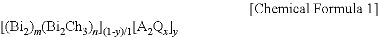

(In the Chemical Formula 1, Ch═Te or Se, A=Li, Na, K, Rb, or Cs, Q=S, Se, or Te, x=1 to 6, and 0≤y≤0.4).

In the Chemical Formula 1, (Bi₂)ₘ(Bi₂Ch₃)ₙ represents a homologous series compound composed of a combination of bilayers of Big and quintuple layers of Bi₂Ch₃. m represents the number of Big bilayers crystallographic unit structure of the thermoelectric material, n represents the number of Bi₂Ch₃ quintuple layers in the crystallographic unit structure of the thermoelectric material, and 1 denotes the greatest common divisor that allows the compositional ratio of Bi and Ch (Te, Se) in the homologous series compound to be expressed as integers.

The thermoelectric material may have polycrystalline properties. The thermoelectric material may be an n-type semiconductor.

The thermoelectric material may be formed by performing a solid-state synthesis reaction on reactants comprising Bi, Te, Se, and A₂Qₓ (A=Li, Na, K, Rb, or Cs; Q=S, Se, or Te; x=1 to 6).

The A may be located in at least one of the interlayer site, interstitial site, and ionic site of the Bi—Te based compound in the thermoelectric material.

A method for forming a thermoelectric material according to the embodiments of the present invention comprises sealing and heating reactants comprising Bi, Te, Se, and A₂Qₓ (A=Li, Na, K, Rb, or Cs; Q=S, Se, or Te; x=1 to 6) to melt and react the reactants, cooling the reaction product to form an ingot, and pulverizing the ingot into powder and sintering the powder.

The thermoelectric material may have the above Chemical Formula 1.

The reactants may be heated at a temperature of 600 to 700° C. for 22 to 26 hours. The sintering may be performed using a spark plasma sintering method.

### Embodiments

Reactants comprising Bi, Te, Se, A₂Qₓ (A=Li, Na, K, Rb, Cs; Q=S, Se, Te; x=1 to 6) are accurately measured according to the target composition and placed in a quartz tube. The tube is then sealed under high vacuum using a high-temperature torch. The sealed reactants are heated at 650° C. for 24 hours to induce melting, followed by cooling to obtain an ingot. The ingot is pulverized into powder and processed using the spark plasma sintering (SPS) method to produce thermoelectric materials in the form of pellets.

The thermoelectric material has the following Chemical Formula 1.

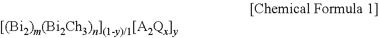

(In the Chemical Formula 1, Ch═Te or Se, A=Li, Na, K, Rb, or Cs, Q=S, Se, or Te, x=1 to 6, and 0≤y≤0.4).

The ratio of m:n:1 in Chemical Formula 1 according to the embodiments of the present invention is as follows. This ratio is calculated based on the unit lattice structure of each solid compound.

(1) m:n:1=0:3:3, (2) m:n:1=1:5:4, (3) m:n:1=2:7:3, (4) m:n:1=3:9:3, (5) m:n:1=1:2:6, (6) m:n:1=3:3:3, (7) m:n:1=2:1:3, (8) m:n:1=15:6:6, (9) m:n:1=3:0:3

The thermoelectric material has a composition in which excess alkali metal and chalcogen elements are present. As a result, the alkali metal atom may be located in at least one of the interlayer site, interstitial site, and ionic site of the Bi—Te based compound. Furthermore, based on these defects, the thermoelectric material locally induces the expression of microstructure of Bi—Te based homologous compound different from the parent compound. For example, BiTe defects may be locally formed within the Bi₂Te₃ lattice.

The thermoelectric properties of the thermoelectric material obtained in the above embodiments were measured. First, to measure the electrical transport properties, a pellet sample obtained through the SPS process was cut and polished into a rectangular parallelepiped specimen with dimensions of 2.5 mm×2.5 mm×10 mm, and the electrical conductivity and Seebeck coefficient were measured. For thermal transport property measurements, the remaining part of the same pellet sample was cut and polished into a disk-shaped specimen with a thickness of 8 mm and a height of 1.5 mm, coated with graphite, and the thermal conductivity was measured.

The thermoelectric materials obtained in the embodiments of the present invention were analyzed using inductively coupled plasma atomic emission spectroscopy (ICP-AES), and it was found to have a non-stoichiometric composition, as shown in Table 1 below.

TABLE 1

| | Average analyzed composition | Average analyzed composition |
|---|---|---|
| Nominal composition | (Before SPS; ICP-AES) | (After SPS; ICP-AES) |
| “Bi₂Te₃-1% K₂Se₆” | K_{0.029}Bi_{2.000}Te_{2.987}Se_{0.053} | K_{0.018}Bi_{2.000}Te_{2.957}Se_{0.059} |
| “Bi₂Te₃-3% K₂Se₆” | K_{0.069}Bi_{2.000}Te_{2.987}Se_{0.157} | K_{0.031}Bi_{2.000}Te_{2.840}Se_{0.182} |
| “Bi₂Te₃-5% K₂Se₆” | K_{0.110}Bi_{2.000}Te_{2.976}Se_{0.302} | K_{0.035}Bi_{2.000}Te_{2.732}Se_{0.305} |
| “Bi₂Te₃-7% K₂Se₆” | K_{0.118}Bi_{2.000}Te_{3.005}Se_{0.445} | K_{0.045}Bi_{2.000}Te_{2.628}Se_{0.429} |
| “Bi₂Te₃-9% K₂Se₆” | K_{0.176}Bi_{2.000}Te_{2.989}Se_{0.531} | K_{0.054}Bi_{2.000}Te_{2.539}Se_{0.542} |
| “Bi₂Te₃-11% K₂Se₆” | K_{0.222}Bi_{2.000}Te_{2.997}Se_{0.659} | K_{0.057}Bi_{2.000}Te_{2.423}Se_{0.672} |
| “Bi₂Te₃-13% K₂Se₆” | K_{0.284}Bi_{2.000}Te_{3.004}Se_{0.809} | K_{0.060}Bi_{2.000}Te_{2.315}Se_{0.801} |

The thermoelectric materials according to the embodiments of the present invention maintain an overall layered structure while incorporating various point defects and heterogeneous structures. In particular, alkali metals are positioned in interlayer and interstitial sites while maintaining the unique layered structure of Bi—Te based materials. This positioning provides additional charge carriers, i.e., electrons, and induces modulation of the electronic band structure. Through this, the reduction in electrical conductivity caused by alloying is minimized, and the Seebeck coefficient is enhanced, thereby maintaining the overall electrical transport properties. Various types of point defects, such as interlayer, interstitial, and ionic sites, are induced, and as a result, the local expression of heterogeneous Bi—Te based homologous compounds maximizes phonon scattering.

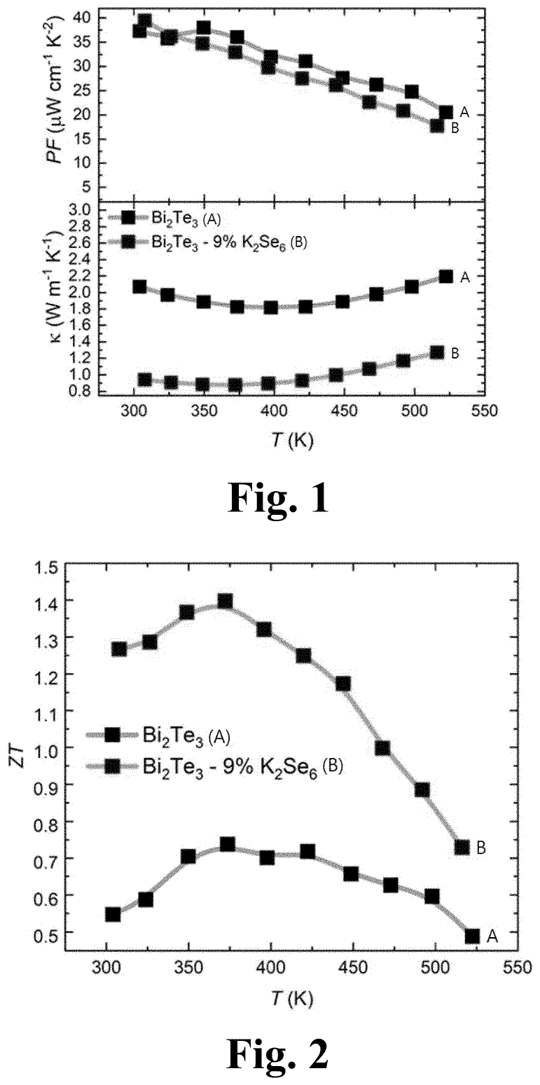

FIG. 1 shows the power factor (PF) and thermal conductivity of Bi₂Te₃-9% K₂Se₆, a thermoelectric material according to one embodiment of the present invention compared with those of Bi₂Te₃, and FIG. 2 shows the power factor (PF) and thermoelectric figure of merit (ZT) of Bi₂Te₃-9% K₂Se₆, a thermoelectric material according to one embodiment of the present invention compared with those of Bi₂Te₃.

Referring to FIGS. 1 and 2, Bi₂Te₃₋₉% K₂Se₆ maintained excellent electrical transport properties of about 40 μW·cm⁻¹·K⁻² at room temperature, while reducing its thermal conductivity to about 0.88 W·m⁻¹·K⁻¹ at 100° C. Furthermore, Bi₂ Te₃-9% K₂Se₆ exhibited a high thermoelectric figure of merit (ZT) of about 1.4 at 100° C.

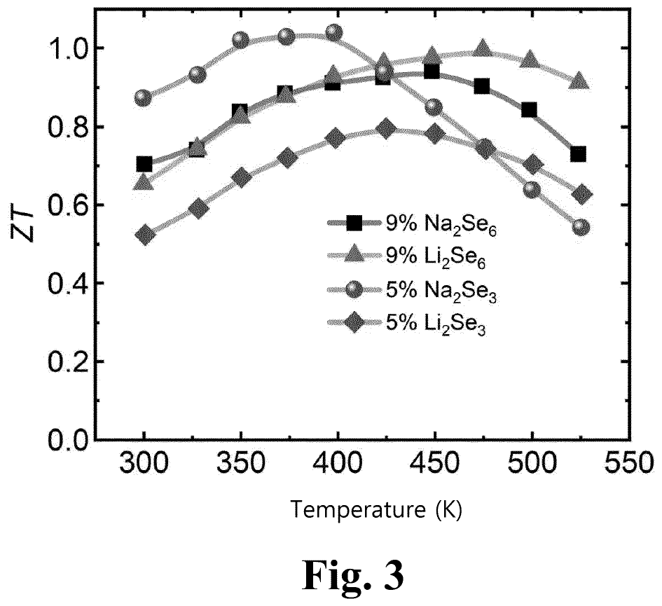

FIG. 3 shows the thermoelectric figure of merit (ZT) of thermoelectric materials according to other embodiments of the present invention.

Referring to FIG. 3, it was found that the thermoelectric figure of merit (ZT) of the thermoelectric material varies depending on the content of A₂Qₓ (Li₂Se₃, Na₂Se₃, Li₂Se₆, Na₂Se₆) and the ratio of alkali metal (Li, Na) to Se. Furthermore, the thermoelectric materials according to the embodiments of the present invention exhibit a high thermoelectric figure of merit.

Although the embodiments of the present invention have been disclosed for illustrative purposes, those skilled in the art will appreciate that the present invention may be embodied in other specific ways without changing the technical spirit or essential features thereof. Therefore, the embodiments disclosed in the present invention are not restrictive but are illustrative. The scope of the present invention is given by the claims, rather than the specification, and also contains all modifications within the meaning and range equivalent to the claims.

### INDUSTRIAL APPLICABILITY

The thermoelectric material according to the embodiments of the present invention may have good performance. The thermoelectric material may possess superior electrical properties and an improved thermoelectric figure of merit. When combined with a p-type material, the thermoelectric material may enable the development of a thermoelectric module with enhanced power generation efficiency.

1. A thermoelectric material having the following Chemical Formula 1. 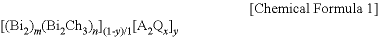
(In the Chemical Formula 1, Ch═Te or Se, A=Li, Na, K, Rb, or Cs, Q=S, Se, or Te, x=1 to 6, and 0≤y≤0.4).

2. The thermoelectric material of claim 1, wherein the thermoelectric material has polycrystalline properties.

3. The thermoelectric material of claim 1, wherein the thermoelectric material is an n-type semiconductor.

4. The thermoelectric material of claim 1, wherein the thermoelectric material is formed by performing a solid-state synthesis reaction on reactants comprising Bi, Te, Se, and A₂Qₓ (A=Li, Na, K, Rb, or Cs; Q=S, Se, or Te; x=1 to 6).

5. The thermoelectric material of claim 1, wherein the A is located in at least one of the interlayer site, interstitial site, and ionic site of the Bi—Te based compound in the thermoelectric material.

6. A method for forming a thermoelectric material comprising;
sealing and heating reactants comprising Bi, Te, Se, and A₂Qₓ (A=Li, Na, K, Rb, or Cs; Q=S, Se, or Te; x=1 to 6) to melt and react the reactants;
cooling the reaction product to form an ingot; and
pulverizing the ingot into powder and sintering the powder.

7. The method of claim 6, wherein the thermoelectric material has the following Chemical Formula 1. 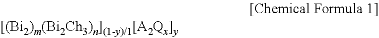
(In the Chemical Formula 1, Ch═Te or Se, A=Li, Na, K, Rb, or Cs, Q=S, Se, or Te, x=1 to 6, and 0≤y≤0.4).

8. The method of claim 6, wherein the thermoelectric material has polycrystalline properties.

9. The method of claim 6, wherein the reactants are heated at a temperature of 600 to 700° C. for 22 to 26 hours.

10. The method of claim 6, wherein the sintering is performed using a spark plasma sintering method.
